(19) United States
(12) Patent Application Publication
(10) Pub. No.: US 2025/0301595 A1
(43) Pub. Date: Sep. 25, 2025

(54) SLIDE RAIL DEVICE AND SERVER RACK

(71) Applicant: Ruijie Networks Co., Ltd., Fuzhou (Fujian) (CN)

(72) Inventor: Dingkui HUA, Fuzhou (CN)

(21) Appl. No.: 19/231,994

(22) Filed: Jun. 9, 2025

Related U.S. Application Data
(63) Continuation of application No. PCT/CN2024/108895, filed on Jul. 31, 2024.

(30) Foreign Application Priority Data
Aug. 9, 2023 (CN) 202322127275.9

(51) Int. Cl. H05K 7/14

(52) U.S. Cl. CPC H05K 7/1489

(57) ABSTRACT

This application discloses a slide rail device and a server rack. The slide rail device is installed between a first upright column and a second upright column of a rack, including: a slide rail assembly; a first fixing assembly including: a latch; and a box, where the box is disposed on a side of the first upright column close to the second upright column, one end of the box is detachably connected to the first upright column via the latch, and another end of the box is connected to the slide rail assembly; and a second fixing assembly, where one end of the second fixing assembly is detachably connected to the second upright column, and another end of the second fixing assembly is connected to the slide rail assembly.

### CROSS-REFERENCE TO RELATED APPLICATIONS

This application is a continuation of International Application No. PCT/CN2024/108895, filed on Jul. 31, 2024, which claims priority to Chinese Patent Application No. 202322127275.9, filed with the China National Intellectual Property Administration on Aug. 9, 2023 and entitled “SLIDE RAIL DEVICE”, which are incorporated herein by reference in their entireties.

### TECHNICAL FIELD

This application relates to the technical field of communication equipment, and in particular, to a slide rail device and a server rack.

### BACKGROUND

A server slide rail is typically fixed to a rack using bolts or nuts. A bracket is fixedly connected to an end of the slide rail. The bracket is provided with a threaded hole. The threaded hole corresponds to a mounting hole on the rack. The mounting hole is a square hole or a circular hole. During installation, the threaded hole on the bracket is aligned with the mounting hole on the rack, and a nut passes through the mounting hole on the rack and is finally rotatably inserted in the threaded hole on the bracket.

### SUMMARY

An exemplary embodiment of this application provides a slide rail device and a server rack. The slide rail device is installed between a first upright column and a second upright column of a rack, including:
a slide rail assembly; and
a first fixing assembly including: a latch; and a box, where the box is disposed on a side of the first upright column close to the second upright column, one end of the box is detachably connected to the first upright column via the latch, and another end of the box is connected to the slide rail assembly; and a second fixing assembly, where one end of the second fixing assembly is detachably connected to the second upright column, and another end of the second fixing assembly is connected to the slide rail assembly.

According to the slide rail device of this application, during installation of the slide rail device, the second fixing assembly is first detachably connected to the second upright column, and then the box is detachably connected to the first upright column, providing convenient operation and improving the operating efficiency of assembling and disassembling the slide rail device.

In an optional technical solution, the first upright column has a first mounting hole, the box is installed on the side of the first upright column close to the second upright column, and the latch passes through the first mounting hole to be in plug-in connection with the box.

In the above embodiment, a screw-free installation method is used to connect the first fixing assembly and the first upright column, and the latch passes through the first mounting hole on the upright column to be in plug-in connection with the box, providing convenient operation and improving the operating efficiency of assembling and disassembling the slide rail device.

In an optional technical solution, the first fixing assembly further includes a first elastic member, the first elastic member is installed on an inner wall of the box, the latch includes a first inserting head, the first inserting head has a hook at an end facing the box, and the hook is snap-fitted with the first elastic member.

In an optional technical solution, the first elastic member includes a connecting plate and a snap-fitting plate, one end of the connecting plate is fixedly connected to the inner wall, another end of the connecting plate is connected to one end of the snap-fitting plate, and the hook is snap-fitted with the snap-fitting plate.

In an optional technical solution, a side of the hook facing away from an insertion direction has a snap-fitting surface, the snap-fitting plate has a snap-fitting hole, and the snap-fitting hole includes a first edge; and when the latch is in a second position, the hook passes through the snap-fitting hole, and the first edge abuts against the snap-fitting surface.

In an optional technical solution, the first elastic member further includes an operating plate, one end of the operating plate is connected to another end of the snap-fitting plate, and the operating plate is configured to drive the snap-fitting plate to disengage from the hook.

In an optional technical solution, another end of the operating plate extends away from the first upright column.

In an optional technical solution, another end of the operating plate extends toward the first upright column.

In an optional technical solution, the latch further includes a second inserting head, the second inserting head is located on a side of the first inserting head in a radial direction, the inner wall is provided with a limiting bridge, and when the latch is in the second position, the second inserting head is clamped by the limiting bridge.

In an optional technical solution, the inner wall includes a first sidewall, a second sidewall, and a third sidewall connected in sequence; the first sidewall is opposite the third sidewall; the first sidewall is provided with a first limiting bridge; the second sidewall is provided with a second limiting bridge; the third sidewall is provided with a third limiting bridge; a first limiting space is formed between the first limiting bridge, the second limiting bridge, and the third limiting bridge; and the second inserting head is inserted in the first limiting space.

In an optional technical solution, the latch includes a latch panel, a first inserting head, a second inserting head, and a third inserting head, where the second inserting head, the first inserting head, and the third inserting head are sequentially arranged on the latch panel.

In an optional technical solution, the slide rail device further includes a slide rail assembly, where the first fixing assembly and the second fixing assembly are respectively disposed at two ends of the slide rail assembly.

In an optional technical solution, the slide rail assembly includes a first slide rail and a second slide rail, the second slide rail has a slide groove, and the first slide rail is slidably installed in the slide groove.

In an optional technical solution, the second fixing assembly includes a latch pin, the second upright column has a second mounting hole, and the latch pin is snap-fitted with the second mounting hole.

In the above embodiment, a screw-free installation method is used to connect the second fixing assembly and the second upright column, and the latch pin passes through the second mounting hole on the upright column to be in plug-in connection with the box, providing convenient operation and improving the operating efficiency of assembling and disassembling the slide rail device.

In an optional technical solution, the second fixing assembly further includes a mounting frame; the mounting frame is C-shaped and includes a fifth sidewall, a sixth sidewall, and a seventh sidewall connected in sequence; the fifth sidewall is opposite the seventh sidewall; the latch pin is installed on a side of the fifth sidewall facing the slide rail assembly; and the seventh sidewall is vertically installed at an end of the second slide rail.

In an optional technical solution, the second fixing assembly further includes a second elastic member; the second elastic member is configured to restrict movement of the latch pin in the second mounting hole; the mounting frame has an avoidance hole; one end of the second elastic member is installed on the second slide rail, and another end thereof passes through the avoidance hole; and the second elastic member is elastic and capable of moving away from the latch pin under an external force and approaching the latch pin under a rebound force.

In an optional technical solution, the latch pin has a second guiding surface, the second mounting hole has a second edge, and during movement of the latch pin from a third position to a fourth position, the second edge slides along the second guiding surface.

In an optional technical solution, the second elastic member includes a connecting segment and a snap-fitting segment, the connecting segment and the snap-fitting segment form a step shape, and the connecting segment is connected to the second slide rail; and during movement of the latch pin from the third position to the fourth position, the second upright column drives the connecting segment to move away from the latch pin, and when the latch pin is in the fourth position, the connecting segment drives the snap-fitting segment to approach the latch pin, and the snap-fitting segment abuts against the second upright column.

In an optional technical solution, a step corresponding to the step shape is located between the fifth sidewall and the seventh sidewall of the mounting frame.

In an optional technical solution, when the second elastic member is in a natural state, a bent portion of the second elastic member and the fifth sidewall form a slot structure, and the slot structure is configured to be snap-fitted with the second upright column.

In an optional technical solution, when the second fixing assembly is unlocked from the second upright column, the second elastic member is located on a side away from the latch pin, and after the second upright column is released from the slot structure, the latch pin is located on an outer side of the second mounting hole.

In an optional technical solution, the latch pin has a second guiding surface, an included angle is formed between the second guiding surface and an insertion direction of the latch pin, an edge of the second mounting hole on a side close to the slide rail assembly is a second edge, and during movement of the latch pin from the third position to the fourth position, the second edge slides along the second guiding surface.

In an optional technical solution, the first fixing assembly includes a first housing and a second housing, the first housing and the second housing are fastened together to form the box, and the first housing is connected to an end of the first slide rail.

In an optional technical solution, the first housing and the slide rail assembly are connected to form a step shape.

### BRIEF DESCRIPTION OF DRAWINGS

To describe the technical solutions of the embodiments of this application more clearly, the following briefly describes the accompanying drawings required for describing the embodiments or the conventional technology. Apparently, the accompanying drawings in the following descriptions show merely some embodiments of this application, and persons of ordinary skill in the art may still derive accompanying drawings of other embodiments from these accompanying drawings without creative efforts.

FIG. 1 is a schematic diagram of installation of a slide rail device and a rack according to an embodiment of this application;

FIG. 2 is a schematic structural diagram of a slide rail device according to an embodiment of this application;

FIG. 3 is a schematic structural diagram of a first fixing assembly when a latch is in a first position A according to an embodiment of this application;

FIG. 4 is a schematic structural diagram of a first fixing assembly when a latch is between a first position A and a second position B according to an embodiment of this application;

FIG. 5 is a schematic structural diagram of a first fixing assembly when a latch is in a second position B according to an embodiment of this application;

FIG. 6 is an enlarged view of a first fixing assembly according to an embodiment of this application;

FIG. 7 is a schematic structural diagram of a first fixing assembly according to another embodiment of this application;

FIG. 8 is a schematic structural diagram of a first fixing assembly from another perspective according to another embodiment of this application;

FIG. 9 is a schematic diagram of assembly of a first fixing assembly and a mounting lug according to another embodiment of this application;

FIG. 10 is a schematic diagram of assembly of a box and a latch according to an embodiment of this application;

FIG. 11 is a schematic structural diagram of a second fixing assembly in a fourth position according to an embodiment of this application; and

FIG. 12 is a schematic structural diagram of a second fixing assembly in a third position according to an embodiment of this application.

### DESCRIPTION OF REFERENCE SIGNS

10. first upright column; 20. second upright column; 1. first fixing assembly; 2. second fixing assembly; 11. latch; 12. box; 101. first mounting hole; 102. second mounting hole; 21. latch pin; 3. slide rail assembly; 31. first slide rail; 32. second slide rail; 321. slide groove; 311. guide groove; 322. limiting screw; 13. first elastic member; 14. first edge; 111. first inserting head; 1110. hook; 121. first sidewall; 122. third sidewall; 1111. rod portion; 1101. first guiding surface; 1102. snap-fitting surface; 131. connecting plate; 132. snap-fitting plate; 133. operating plate; 1321. snap-fitting hole; 1220. operating hole; 112. second inserting head; 1211. first limiting bridge; 1231. second limiting bridge; 1221. third limiting bridge; 113. third inserting head; 124. fourth sidewall; 1241. first insertion hole; 1242. second insertion hole; 1243. third insertion hole; 1201. first housing; 1202. second housing; 12021. fixing plate; 40. mounting lug; 301. first connecting plate; 302. second connecting plate; 310. recess; 30. mounting frame; 201. fifth sidewall; 202. sixth sidewall; 203. seventh sidewall; 23. second elastic member; 204. avoidance hole; 300. slot structure; 231. connecting segment; 232. snap-fitting segment; 211. second guiding surface; and 1021. second edge.

### DESCRIPTION OF EMBODIMENTS

The following clearly and thoroughly describes the technical solutions in the embodiments of this application with reference to the accompanying drawings in the embodiments of this application. Apparently, the described embodiments are only some rather than all embodiments of this application. All other embodiments obtained by persons of ordinary skill in the art based on the embodiments of this application without creative efforts shall fall within the protection scope of this application. In the description of the embodiments of this application, unless otherwise specified, “/” means “or”, for example, A/B may mean A or B; “and/or” in the text is merely an association relationship describing associated objects, indicating that three relationships may exist. For example, A and/or B may indicate the following three cases: presence of only A; presence of both A and B; and presence of only B. In addition, in the description of the embodiments of this application, “multiple” means two or more.

The following terms “first”, “second”, and the like are merely for the purpose of description, and shall not be understood as any indication or implication of relative importance or any implicit indication of the number of technical features indicated. Therefore, a feature limited by “first” or “second” may explicitly or implicitly include one or more such features. In the description of the embodiments of this application, unless otherwise specified, “multiple” means two or more.

In the description of this application, it should be noted that, unless otherwise specified and defined explicitly, the terms “mounting”, “connection”, “join”, and “fastening” should be understood in their general senses. For example, they may refer to a fixed connection, a detachable connection, or an integral connection, and may refer to a direct connection, an indirect connection via an intermediate medium, or an internal communication between two elements. Persons of ordinary skill in the art can understand specific meanings of these terms in the embodiments of this application as suitable to specific situations.

In the description of this application, the orientations or positional relationships indicated by the terms “center”, “upper”, “lower”, “front”, “rear”, “left”, “right”, “vertical”, “horizontal”, “top”, “bottom”, “inside”, “outside”, and the like are based on the orientations or positional relationships as shown in the accompanying drawings. These terms are merely for the ease and brevity of description of this application rather than indicating or implying that the means or components mentioned must have specific orientations or must be constructed or manipulated according to specific orientations, and therefore shall not be construed as any limitations on embodiments of this application.

First, an application scenario is introduced. In communication equipment, a communication box typically needs to be installed on a cabinet or a rack, and the communication box may be a server. The server has a size of 1 U, where U is a unit representing an external dimension of a server and serves as an abbreviation of “unit.” When a 19-inch 1 U server installed on a rack is used as an example, an installation space provided by the rack typically has a width of 450 mm, a height of 44.45 mm, and a depth determined by a distance between front and rear upright columns of the rack. The 19-inch 1 U server has a width of 436-442 mm and a height of 43.6-44 mm. The server is generally connected to the front upright column through mounting lugs, and the mounting lugs are fixed to the upright column using floating nuts. When the length of the server exceeds 350 mm, the rear end of the server may sag due to gravity. Therefore, a slide rail device is needed to laterally support the server to prevent the rear end of the server from sagging into the installation space of the server below due to an excessive length, which otherwise affects the installation and removal operations of the server below.

The slide rail device is configured to support the communication box, which can prevent the rear end of the communication box from sagging so as not to affect the installation and removal of the communication box below. Typically, the slide rail device is fixed to the front and rear upright columns using screws. Tools are required for assisting installation and removal operations, and these operations are typically completed with the need of the coordinated operations of two people, so that the operation process is relatively cumbersome. An embodiment of this application provides a slide rail device, which can solve the problem of inconvenient operation during the installation and removal of the slide rail device.

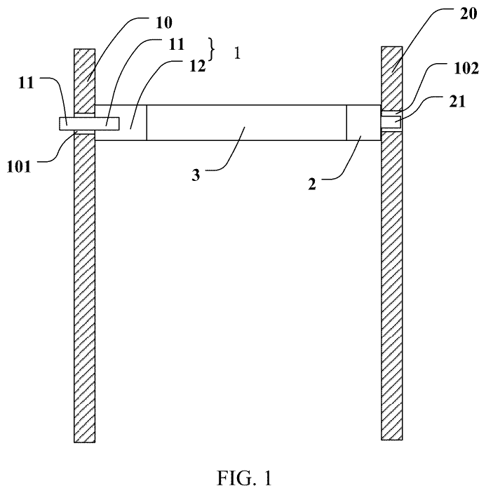

FIG. 1 is a schematic diagram of installation of a slide rail device and a rack according to an embodiment of this application. As shown in FIG. 1, a slide rail device provided by an embodiment of this application is installed between a first upright column 10 and a second upright column 20 of a rack. The rack includes four upright columns, and the four upright columns are installed perpendicular to the ground. Two of the four upright columns are front upright columns, and the other two are rear upright columns. The first upright column may be regarded as a front upright column, and the second upright column may be regarded as a rear upright column. The slide rail device includes a first fixing assembly 1 and a second fixing assembly 2, where the first fixing assembly 1 is installed on the first upright column, and the second fixing assembly 2 is installed on the second upright column. The slide rail device is installed on the rack through the first fixing assembly 1 and the second fixing assembly 2. The first fixing assembly 1 includes a latch 11 and a box 12, the first upright column 10 has a first mounting hole 101, and the box 12 is installed on a side of the first upright column 10 close to the second upright column 20. The latch 11 passes through the first mounting hole 101 from a side of the first upright column 10 facing away from the box 12 to be in plug-in connection with the box 12, achieving fixation of the first fixing assembly 1 to the first upright column 10. The second fixing assembly 2 includes a latch pin 21, the second upright column 20 has a second mounting hole 102, and the latch pin 21 is snap-fitted with the second mounting hole 102, achieving fixation of the second fixing assembly 2 to the second upright column 20.

In the above embodiment, during installation of the slide rail device, the latch pin 21 of the second fixing assembly 2 is first inserted in the second mounting hole 102 to be snap-fitted with the second mounting hole 102, then the box 12 abuts against the first upright column 10, and finally, the latch 11 passes through the first mounting hole 101 to be inserted in the box 12 for plug-in connection with the box 12. The slide rail device of this application adopts a screw-free installation method, providing convenient operation and improving the operating efficiency of assembling and disassembling the slide rail device.

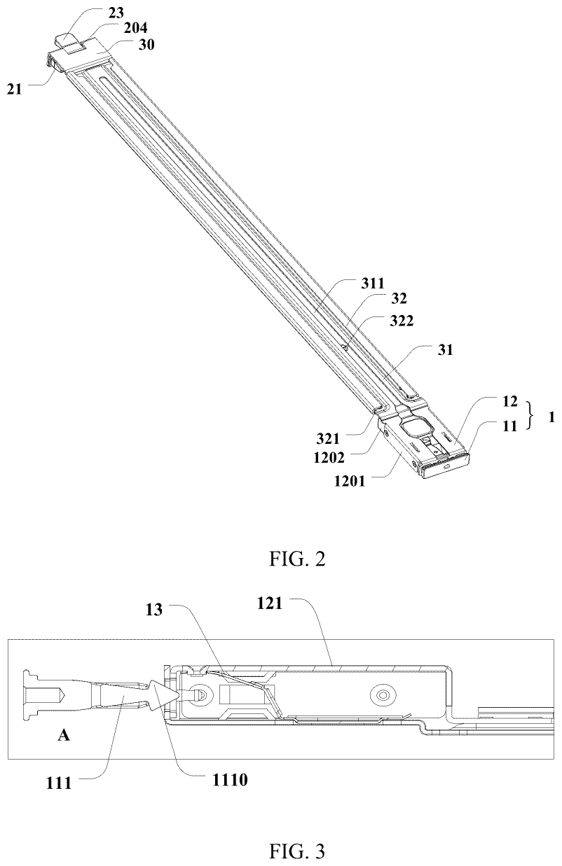

FIG. 2 is a schematic structural diagram of a slide rail device according to an embodiment of this application. Referring to FIG. 1 and FIG. 2, in an embodiment, the slide rail device further includes a slide rail assembly 3, where the first fixing assembly 1 and the second fixing assembly 2 are respectively disposed at two ends of the slide rail assembly 3. The slide rail assembly 3 may be a strip-shaped structure, with an extension direction perpendicular to the first upright column 10 and the second upright column 20. Specifically, the slide rail assembly 3 may include a first slide rail 31 and a second slide rail 32, where the second slide rail 32 may have a slide groove 321, and the first slide rail 31 is slidably installed in the slide groove 321. During use, the first slide rail 31 may be pulled to achieve relative sliding of the first slide rail 31 and the second slide rail 32, so that an extension length of the slide rail assembly 3 is adjusted, thereby allowing the slide rail device to adapt to a distance between the first upright column 10 and the second upright column 20.

Still referring to FIG. 2, to prevent the first slide rail 31 from disengaging from the slide groove of the second slide rail 32, the first slide rail 31 may be provided with a guide groove 311, and an extension direction of the guide groove 311 is consistent with an extension direction of the first slide rail 31. The second slide rail 32 is provided with a limiting screw 322, and the limiting screw 322 passes through the guide groove 311 and is fixedly connected to the second slide rail 32. During relative sliding of the first slide rail 31 and the second slide rail 32, the limiting screw 322 slides along the guide groove 311. In the embodiment shown in FIG. 2, the guide groove 311 has a closed end and an open end, where the closed end faces away from a pulling direction of the first slide rail. In other embodiments, two ends of the guide groove 311 are closed.

In an embodiment, two sides of the communication box are provided with hanging nails (not shown in the figure), the hanging nails may be hung in the guide groove 311 and may slide along the guide groove 311, achieving connection between the communication box and the slide rail device, thereby completing the installation operation.

The structure of the first fixing assembly 1 is described below.

FIG. 5 is a schematic structural diagram of a first fixing assembly according to an embodiment of this application. As shown in FIG. 5, the first fixing assembly 1 further includes a first elastic member 13. The first elastic member 13 is installed on an inner wall of the box 12. The latch 11 may include a first inserting head 111. The first inserting head 111 may have a hook 1110 at an end facing the box 12, and a side of the hook 1110 facing the first upright column 10 bends inwardly, that is, the hook 1110 is recessed inwardly in a radial direction to form a recessed portion. When the latch 11 is inserted in the box, the recessed portion cooperates with the first elastic member 13 to form snap-fitting. The hook 1110 is snap-fitted with the first elastic member 13 to achieve insertion and fixation of the latch 11 to the box 12. Specifically, in this embodiment, the box 12 includes a first sidewall 121, a second sidewall (not shown in the figure), a third sidewall 122, and a fourth sidewall (not shown in the figure) connected to each other, where the first sidewall 121 is opposite the third sidewall 122, and the second sidewall is opposite the fourth sidewall. The first sidewall 121, the second sidewall, the third sidewall 122, and the fourth sidewall enclose to form an accommodating cavity of the box 12. The first elastic member 13 may be an elastic piece, one end of the first elastic member 13 is fixedly connected to the first sidewall 121, and an acute included angle is formed between the first elastic member 13 and the first sidewall 121. Due to the elasticity, the elastic piece may approach the first sidewall 121 under an external force and move away from the first sidewall 121 under a rebound force.

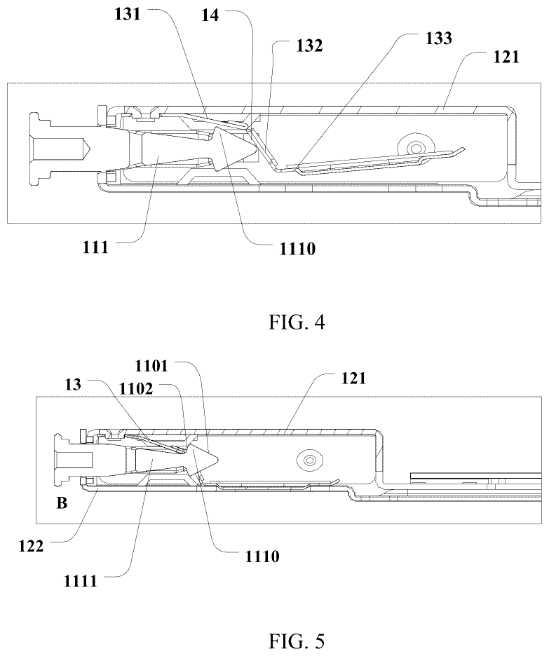

FIG. 3 to FIG. 5 illustrate three states of the latch 11 moving from a first position A to a second position B. As shown in FIG. 3, the latch 11 is in the first position A and in a state of being not inserted in the box 12. As shown in FIG. 4, when the latch 11 moves from the first position A to the second position B, that is, when the latch 11 is between the first position A and the second position B, the first inserting head 111 extends into the accommodating cavity of the box 12, and the hook 1110 at the end of the first inserting head 111 presses against the first elastic member 13, allowing the first elastic member 13 to approach the first sidewall 121. As shown in FIG. 5, the latch 11 is in the second position B, that is, the latch 11 is in a state of having been inserted in the box 12, the first elastic member 13 is released, moves away from the first sidewall 121 under the rebound force, and extends into the hook 1110, achieving snap-fitting between the first elastic member 13 and the hook 1110. After the first elastic member 13 is snap-fitted with the hook 1110, the first elastic member 13 restricts the latch 11 from sliding from the second position B to the first position A, thereby achieving locking of the latch 11 to the box 12.

Still referring to FIG. 5, in an embodiment, the first inserting head 111 may further include a rod portion 1111, the hook 1110 is connected to an end of the rod portion 1111, the hook 1110 has a first guiding surface 1101 and a snap-fitting surface 1102 connected to each other, and an included angle is formed between the first guiding surface 1101 and the snap-fitting surface 1102. In an embodiment, a cross-section of the first inserting head 111 perpendicular to the first sidewall 121 may be arrow-shaped, that is, the hook 1110 and the rod portion 1111 form a step shape. When the latch 11 moves from the first position A to the second position B, an end of the first elastic member 13 facing the first inserting head 111 is driven by the hook 1110, allowing the first elastic member 13 to gradually approach the first sidewall 121. When the latch 11 is in the second position B, the first elastic member 13 rebounds and abuts against the snap-fitting surface 1102, that is, the end of the first elastic member 13 facing the first inserting head 111 is clamped into a bent portion of the step (the recessed portion), restricting the latch 11 from moving from the second position B to the first position A. In an implementation, when the latch 11 is in the second position B, the first guiding surface 1101 may be parallel to the first elastic member 13, and the snap-fitting surface 1102 is perpendicular to the first elastic member 13. It may be noted that the figure shows that the first inserting head 111 has two hooks 1110, one hook 1110 faces the first sidewall 121, and the other hook 1110 faces the third sidewall 122. In another embodiment, only one hook facing the first sidewall 121 or the third sidewall 122 may alternatively be provided.

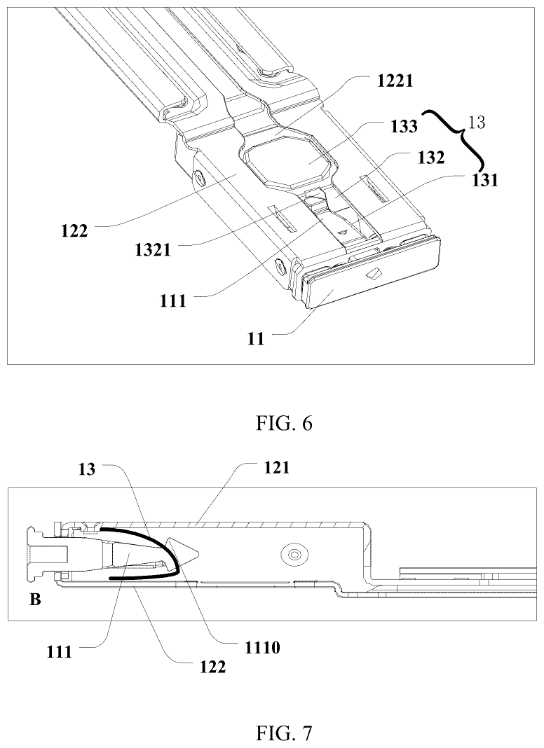

FIG. 6 is an enlarged view of a first fixing assembly according to an embodiment of this application. Referring to FIG. 4, FIG. 5, and FIG. 6, to allow the hook 1110 to disengage from the first elastic member 13 and achieve unlocking of the latch 11 from the box 12, in an implementation, the first elastic member 13 includes a connecting plate 131, a snap-fitting plate 132, and an operating plate 133 connected in sequence. The connecting plate 131 is fixedly installed on the first sidewall 121. An acute included angle is formed between the connecting plate 131 and the first sidewall 121. The hook 1110 is snap-fitted with the snap-fitting plate 132. The operating plate 133 is configured to drive the snap-fitting plate 132 to disengage from the hook 1110. Specifically, when the first elastic member 13 is prepared, a strip-shaped plate may be selected and bent into three segments to form a roughly Z shape. The structures of the three segments are the connecting plate 131, the snap-fitting plate 132, and the operating plate 133, respectively. The snap-fitting plate 132 has a snap-fitting hole 1321, the snap-fitting hole 1321 may be square, and an edge of the snap-fitting hole 1321 close to the first sidewall 121 is a first edge 14. When the latch 11 is in the second position B, the hook 1110 passes through the snap-fitting hole 1321, and at this time, the first edge 14 abuts against the snap-fitting surface 1102, restricting the latch 11 from moving from the second position B to the first position A. When the latch 11 needs to be removed, the operating plate 133 is pressed, the operating plate 133 applies a force to the snap-fitting plate 132, and the connecting plate 131 is driven by the snap-fitting plate 132 to move up so as to disengage from the hook, that is, the snap-fitting plate 132 and the connecting plate 131 are driven to approach the first sidewall 121, so that the first edge 14 moves away from the snap-fitting surface 1102 until the first elastic member 13 completely disengages from the hook 1110. At this time, the latch 11 is unlocked from the box 12, and a user can pull the latch 11 out of the box 12, that is, the latch 11 moves from the second position B to the first position A.

FIG. 7 is a schematic structural diagram of a first fixing assembly according to another embodiment of this application. The difference between the embodiment in FIG. 7 and the embodiments described in FIG. 4 to FIG. 6 may only be that the first elastic member 13 in FIG. 7 is a C-shaped arc elastic piece. That is, the first elastic member 13 in FIG. 7 is not limited to the shape described in the above embodiments and may also be an arc elastic piece, and the arc elastic piece is roughly C-shaped, with one end connected to the first sidewall 121, and another end serving as a pressing operation end. A position in the middle of the arc elastic piece corresponding to the hook 1110 is provided with a snap-fitting hole (not shown in the figure), and the hook 1110 hooks onto an upper edge (that is, the first edge) of the snap-fitting hole to achieve locking of the latch 11 to the box 12. The pressing operation end squeezes the arc elastic piece to allow the hook 1110 to disengage from the snap-fitting hole, thereby achieving unlocking.

It may be understood that the first elastic member 13 shown in FIG. 7 may also be applied to other embodiments.

Referring to FIG. 6, in some of the above embodiments, the third sidewall 122 of the box 12 is provided with an operating hole 1220, helping a user to access the operating hole 1220 to press the operating plate 133 or the operation end of the first elastic member 13 for unlocking the latch 11.

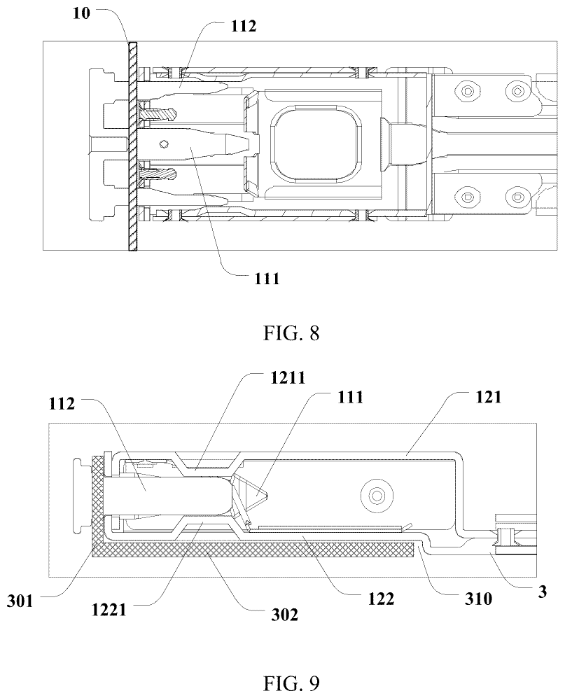

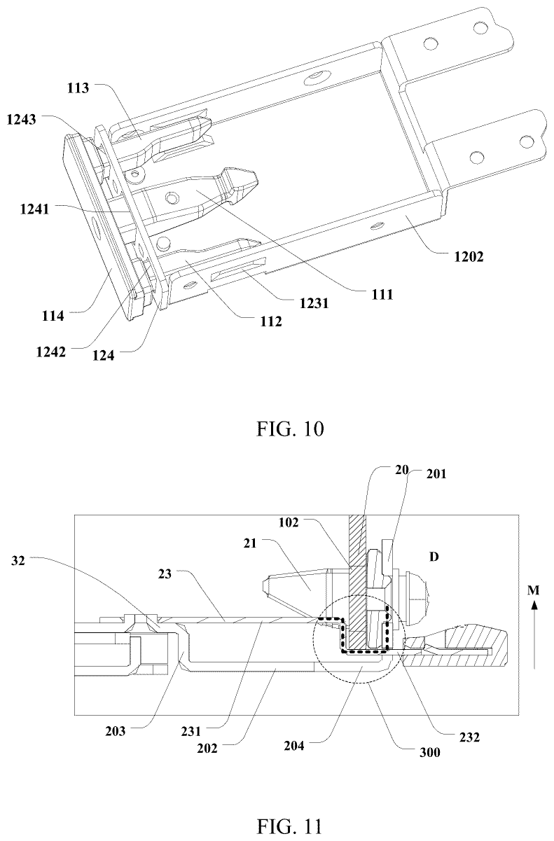

FIG. 8 is a schematic structural diagram of a first fixing assembly from another perspective according to another embodiment of this application, FIG. 9 is a schematic diagram of assembly of a first fixing assembly and a mounting lug according to another embodiment of this application, and FIG. 10 is a schematic diagram of assembly of a box and a latch according to an embodiment of this application.

The difference between the embodiments of FIG. 8 and FIG. 9 and the embodiments of FIG. 4 to FIG. 6 may only be that in the embodiment of FIG. 8, a second inserting head 112 and a corresponding limiting bridge structure are provided. However, it may be understood that the second inserting head 112 and the corresponding limiting bridge structure in FIG. 8 may also be applied to other embodiments.

Referring to FIG. 8 to FIG. 10, to make the plug-in connection of the latch 11 with the box 12 more secure, in an embodiment, the latch 11 further includes a second inserting head 112; the second inserting head 112 is located on a side of the first inserting head 111, and the second inserting head 112 and the first inserting head 111 are arranged along an extension direction of the first upright column 10; the first sidewall 121 is provided with a first limiting bridge 1211; the second sidewall is provided with a second limiting bridge 1231; the third sidewall 122 is provided with a third limiting bridge 1221; a first limiting space is formed between the first limiting bridge 1211, the second limiting bridge 1231, and the third limiting bridge 1221; the second inserting head 112 is inserted in the first limiting space; and the first limiting bridge 1211, the second limiting bridge 1231, and the third limiting bridge 1221 clamp the second inserting head 112 from three directions.

The difference between the embodiment of FIG. 10 and the embodiments of FIG. 4 to FIG. 6 may also be that in the embodiment of FIG. 10, a third inserting head 113 and a corresponding limiting bridge structure are further provided. However, it may be understood that the third inserting head 113 and the corresponding limiting bridge structure in FIG. 10 may also be applied to other embodiments.

Referring to FIG. 10, the latch may further include a third inserting head 113, where the third inserting head 113 and the second inserting head 112 are symmetrically disposed on two sides of the first inserting head 111. A position of the box 12 corresponding to the third inserting head 113 is provided with a fourth limiting bridge, a fifth limiting bridge, and a sixth limiting bridge (not shown in the figure), and an accommodating space is formed. The third inserting head 113 makes the plug-in connection of the latch 11 with the box 12 more secure and allows for even force distribution on the latch 11.

In an embodiment, the latch 11 includes a latch panel 114, where the second inserting head 112, the first inserting head 111, and the third inserting head 113 are sequentially arranged on the latch panel 114. The box 12 includes a fourth sidewall 124 perpendicular to an insertion direction of the latch 11; and the first sidewall 121, the second sidewall, and the third sidewall 122 are respectively connected to the fourth sidewall 124. The fourth sidewall 124 has a first insertion hole 1241, a second insertion hole 1242, and a third insertion hole 1243. The first upright column 10 has multiple first mounting holes 101, where the multiple first mounting holes 101 are arranged along the extension direction of the first upright column 10. Positions of the first insertion hole 1241, the second insertion hole 1242, and the third insertion hole 1243 respectively correspond to a position of any first mounting hole 101. When the latch 11 is in plug-in connection with the box 12, the first inserting head 111 sequentially passes through the first mounting hole 101 and the first insertion hole 1241, the second inserting head 112 sequentially passes through the first mounting hole 101 and the second insertion hole 1242, and the third inserting head 113 sequentially passes through the first mounting hole 101 and the third insertion hole 1243. Sizes of the three insertion holes are roughly the same as those of rod portions of the three plugs, making the plug-in connection of the latch with the box more secure.

Referring to FIG. 1 and FIG. 10, in an embodiment, the first fixing assembly 1 may further include a first housing 1201 and a second housing 1202, where the first housing 1201 and the second housing 1202 are fastened together to form the box 12, and the first housing 1201 is connected to an end of the first slide rail 31. Specifically, the first housing 1201 and the first slide rail 31 are prepared by an integral molding process, and the second housing 1202 is connected to the first housing 1201 by riveting or screwing. The second housing 1202 is further provided with a fixing plate 12021, and the fixing plate 12021 is configured to be connected to the first slide rail 31.

As shown in FIG. 9, during installation of a communication box, two ends of the communication box may further be provided with L-shaped mounting lugs 40, and the communication box is connected to the first upright column (not shown in the figure) through the mounting lugs 40. Specifically, the mounting lug 40 includes a first connecting plate 301 and a second connecting plate 302 perpendicular to each other, the second connecting plate 302 is connected to a sidewall of the communication box (not shown in the figure), and the first connecting plate 301 is connected to the first upright column. The third sidewall 122 of the box and the slide rail assembly 3 form a step shape to form a recess 310, and the recess 310 is used for accommodating the second connecting plate 302 of the mounting lug 40. During installation of the communication box, the second connecting plate 302 is located between the third sidewall 122 and the communication box and is located in the recess 310. This allows for a small gap between the communication box and the first slide rail and a small lateral space occupied by the communication box, thereby making the overall structure of the equipment more compact.

It may be understood that in other embodiments, mounting lugs of other structures may also be used, and this application does not impose particular limitations on this.

The structure of the second fixing assembly 2 is described below.

FIG. 11 is a schematic structural diagram of a second fixing assembly according to an embodiment of this application. As shown in FIG. 11, in an embodiment, the second fixing assembly 2 includes a mounting frame 30 and a latch pin 21, where the mounting frame 30 is C-shaped and includes a fifth sidewall 201, a sixth sidewall 202, and a seventh sidewall 203 connected in sequence; the fifth sidewall 201 is opposite the seventh sidewall 203; the seventh sidewall 203 is vertically installed at an end of the second slide rail 32; and the latch pin 21 is installed on the fifth sidewall 201. Specifically, the latch pin 21 faces the second slide rail 32. An insertion direction of the latch pin 21 is opposite to an insertion direction of the latch. When the latch pin 21 is inserted in the second mounting hole 102, the second upright column 20 is located between the fifth sidewall 201 and the seventh sidewall 203.

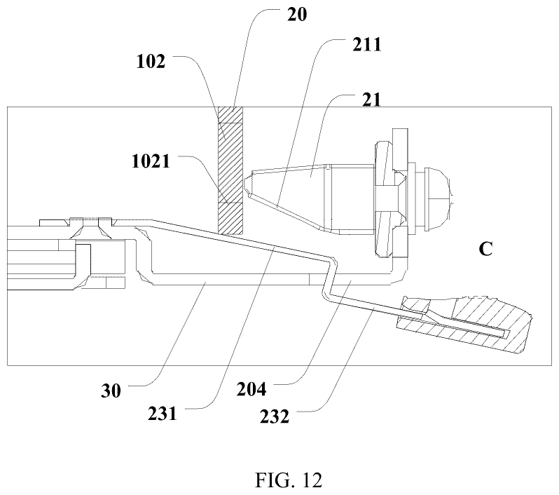

FIG. 12 is a schematic structural diagram of a second fixing assembly in a third position according to an embodiment of this application. Referring to FIG. 11 and FIG. 12, to improve the reliability of the connection between the second fixing assembly 2 and the second upright column 20, in an embodiment, the second fixing assembly 2 further includes a second elastic member 23, where the second elastic member 23 is configured to restrict movement of the latch pin 21 in the second mounting hole 102, preventing the latch pin 21 from disengaging from the second mounting hole 102 so as not to cause the slide rail device to detach from the rack. Specifically, the mounting frame 30 has an avoidance hole 204, and the avoidance hole 204 is used to avoid the second elastic member 23. The avoidance hole 204 is located on both the fifth sidewall 201 and the sixth sidewall 202. That is, the avoidance hole 204 is provided at a corner of the mounting frame 30 away from the slide rail assembly 3, allowing for a large range of movement for the second elastic member. One end of the second elastic member 23 is installed on the second slide rail 32, and another end thereof passes through the avoidance hole 204; and an extension direction of the second elastic member 23 is consistent with an extension direction of the slide rail assembly 3. The second elastic member 23 may be an elastic piece which is elastic and capable of moving away from the latch pin 21 under an external force and approaching the latch pin 21 under a rebound force. During installation of the slide rail device, the second elastic member 23 abuts against the second upright column 20, and the slide rail assembly 3 is pulled to move the latch pin 21 from a third position C to a fourth position D. During this process, the second elastic member 23 is squeezed by the second upright column 20 to gradually move away from the latch pin 21 but always remain in a state of abutting against the second upright column 20. The second elastic member 23 restricts the latch pin 21 from moving in the second mounting hole 102 along a first direction M, the first direction being perpendicular to an insertion direction of the latch pin and perpendicular to the sixth sidewall.

The second elastic member 23 includes a connecting segment 231 and a snap-fitting segment 232, where the connecting segment 231 and the snap-fitting segment 232 form a step shape, and a step is located between the fifth sidewall 201 and the seventh sidewall 203 of the C-shaped mounting frame 30. When the second elastic member 23 is in a natural state, a bent portion of the second elastic member 23 and the fifth sidewall 201 form a slot structure 300, and the slot structure 300 is configured to be snap-fitted with the second upright column 20. During movement of the latch pin 21 from the third position C to the fourth position D, the second upright column 20 drives the connecting segment 231 to move away from the latch pin 21. When the latch pin 21 is in the fourth position D, that is, when the latch pin 21 is snap-fitted with the second mounting hole 102, the connecting segment 231 drives the snap-fitting segment 232 to approach the latch pin 21 under a rebound force, the second upright column 20 is snap-fitted with the slot structure 300, and the snap-fitting segment 232 abuts against the second upright column 20. At this time, the latch pin 21 cannot move along an extension direction of the slide rail assembly, achieving locking of the second fixing assembly 2 to the second upright column 20. When the second fixing assembly 2 needs to be unlocked from the second upright column 20, the second elastic member 23 may be pulled such that the second elastic member 23 moves to a side away from the latch pin 21, the second upright column 20 is released from the slot structure 300, and then the latch pin 21 is removed from the second mounting hole 102.

Still referring to FIG. 12, to allow the latch pin 21 to be inserted in the second mounting hole 102 more smoothly, the latch pin 21 has a second guiding surface 211, and an included angle is formed between the second guiding surface 211 and an insertion direction of the latch pin 21. An edge of the second mounting hole 102 on a side close to the slide rail assembly 3 is a second edge 1021. During movement of the latch pin 21 from the third position C to the fourth position D, the second edge 1021 slides along the second guiding surface 211.

In an embodiment, two latch pins 21 may be provided and are symmetrically installed on two sides of the second elastic member 23 along an extension direction of the second upright column 20. Specifically, the second upright column 20 includes multiple second mounting holes 102, where the multiple second mounting holes 102 are arranged along the extension direction of the second upright column 20. During installation of the second fixing assembly 2, the two latch pins 21 are respectively snap-fitted with different second mounting holes 102, allowing for high reliability of the connection between the slide rail device and the rack.

Apparently, persons skilled in the art can make various modifications and variations to this application without departing from the spirit and scope of this application. Thus, if these modifications and variations of this application fall within the scope of the claims of this application and their equivalent technologies, this application is also intended to include these modifications and variations.

What is claimed is:

1. A slide rail device, installed between a first upright column and a second upright column of a rack, comprising:
a slide rail assembly;
a first fixing assembly comprising:
a latch; and
a box, wherein the box is disposed on a side of the first upright column close to the second upright column, one end of the box is detachably connected to the first upright column via the latch, and another end of the box is connected to the slide rail assembly; and
a second fixing assembly, wherein one end of the second fixing assembly is detachably connected to the second upright column, and another end of the second fixing assembly is connected to the slide rail assembly.

2. The slide rail device according to claim 1, wherein the first upright column has a first mounting hole, the box is installed on the side of the first upright column close to the second upright column, and the latch passes through the first mounting hole to be in plug-in connection with the box.

3. The slide rail device according to claim 1, wherein the first fixing assembly further comprises a first elastic member, the first elastic member is installed on an inner wall of the box, the latch comprises a first inserting head, the first inserting head has a hook at an end facing the box, and the hook is snap-fitted with the first elastic member.

4. The slide rail device according to claim 3, wherein the first elastic member comprises a connecting plate and a snap-fitting plate, one end of the connecting plate is fixedly connected to the inner wall, another end of the connecting plate is connected to one end of the snap-fitting plate, and the hook is snap-fitted with the snap-fitting plate.

5. The slide rail device according to claim 4, wherein a side of the hook facing away from an insertion direction has a snap-fitting surface, the snap-fitting plate has a snap-fitting hole, and the snap-fitting hole comprises a first edge; and
when the latch is in a second position, the hook passes through the snap-fitting hole, and the first edge abuts against the snap-fitting surface.

6. The slide rail device according to claim 4, wherein the first elastic member further comprises an operating plate, one end of the operating plate is connected to another end of the snap-fitting plate, and the operating plate is configured to drive the snap-fitting plate to disengage from the hook.

7. The slide rail device according to claim 6, wherein another end of the operating plate extends away from the first upright column.

8. The slide rail device according to claim 6, wherein another end of the operating plate extends toward the first upright column.

9. The slide rail device according to claim 1, wherein the latch further comprises a second inserting head, the second inserting head is located on a side of the first inserting head in a radial direction, an inner wall of the box is provided with a limiting bridge, and when the latch is in a second position, the second inserting head is clamped by the limiting bridge.

10. The slide rail device according to claim 9, wherein
the inner wall comprises a first sidewall, a second sidewall, and a third sidewall connected in sequence; the first sidewall is opposite the third sidewall; the first sidewall is provided with a first limiting bridge; the second sidewall is provided with a second limiting bridge; the third sidewall is provided with a third limiting bridge; a first limiting space is formed between the first limiting bridge, the second limiting bridge, and the third limiting bridge; and the second inserting head is inserted in the first limiting space.

11. The slide rail device according to claim 1, wherein the slide rail assembly comprises a first slide rail and a second slide rail, the second slide rail has a slide groove, and the first slide rail is slidably installed in the slide groove.

12. The slide rail device according to claim 11, wherein the second fixing assembly comprises a latch pin, the second upright column has a second mounting hole, and the latch pin is snap-fitted with the second mounting hole.

13. The slide rail device according to claim 12, wherein the second fixing assembly further comprises a mounting frame; the mounting frame is C-shaped and comprises a fifth sidewall, a sixth sidewall, and a seventh sidewall connected in sequence; the fifth sidewall is opposite the seventh sidewall; the latch pin is installed on a side of the fifth sidewall facing the slide rail assembly; and the seventh sidewall is vertically installed at an end of the second slide rail.

14. The slide rail device according to claim 13, wherein the second fixing assembly further comprises a second elastic member; the second elastic member is configured to restrict movement of the latch pin in the second mounting hole; the mounting frame has an avoidance hole; one end of the second elastic member is installed on the second slide rail, and another end of the second elastic member passes through the avoidance hole; and the second elastic member is elastic and capable of moving away from the latch pin under an external force and approaching the latch pin under a rebound force.

15. The slide rail device according to claim 14, wherein the second elastic member comprises a connecting segment and a snap-fitting segment, the connecting segment and the snap-fitting segment form a step shape, and the connecting segment is connected to the second slide rail; and
during movement of the latch pin from a third position to a fourth position, the second upright column drives the connecting segment to move away from the latch pin, and when the latch pin is in the fourth position, the connecting segment drives the snap-fitting segment to approach the latch pin, and the snap-fitting segment abuts against the second upright column.

16. The slide rail device according to claim 15, wherein a step corresponding to the step shape is located between the fifth sidewall and the seventh sidewall of the mounting frame.

17. The slide rail device according to claim 14, wherein when the second elastic member is in a natural state, a bent portion of the second elastic member and the fifth sidewall form a slot structure, and the slot structure is configured to be snap-fitted with the second upright column.

18. The slide rail device according to claim 17, wherein when the second fixing assembly is unlocked from the second upright column, the second elastic member is located on a side away from the latch pin, and after the second upright column is released from the slot structure, the latch pin is located on an outer side of the second mounting hole.

19. The slide rail device according to claim 12, wherein the latch pin has a second guiding surface, the second mounting hole has a second edge, and during movement of the latch pin from a third position to a fourth position, the second edge slides along the second guiding surface.

20. A server rack, comprising: the slide rail device according to claim 1.
